(19) United States
(12) Patent Application Publication
(10) Pub. No.: US 2008/0296608 A1
(43) Pub. Date: Dec. 4, 2008

(54) Light-emitting device

(75) Inventors: Hiroyuki Tajima, Aichi-ken (JP); Shigeo Takeda, Aichi-ken (JP); Yukihiro Demukai, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOESEI CO., LTD., Aichi-ken (JP)

(21) Appl. No.: 12/155,061

(22) Filed: May 29, 2008

(30) Foreign Application Priority Data
May 31, 2007 (JP) 2007-145669

(51) Int. Cl. H01L 33/00

(52) U.S. Cl. 257/100; 257/E33.059

(57) ABSTRACT

A light-emitting element 10 is fixed on a lead frame 20 with a die-bonding member 13. The light-emitting element 10 is sealed with a silicone resin 22 and further sealed with an epoxy resin 24 from above the silicone resin 22. The die-bonding member 13 is obtainable by dispersing titanium oxide into an alicyclic epoxy resin obtained by curing an alicyclic epoxy compound with a curing agent.

### BACKGROUND OF THE INVENTION

1. Field of the Invention

This invention relates to a light emission device wherein a light-emitting element is sealed with a resin sealant material. According to the light emission device of this invention, it is possible to prevent discoloration of a die-bonding member that fixes the light-emitting element to a substrate.

2. Description of the Related Art

A light emission device wherein a light-emitting element is fixed on a substrate with a die-bonding member and protected by sealing with a transparent resin has heretofore been known. However, achievement of increased brightness of the light-emitting element has entailed a problem that a sealant material is gradually decomposed and blackened with heat and light from the light-emitting element to be reduced in transmittance, resulting in a reduction in luminous intensity.

As a countermeasure for the problem, a silicone resin excellent in heat resistance and light resistance has been developed as a sealant material for the light-emitting device (Patent Publications 1 and 2), and the light-emitting device is sealed with the silicone resin and further sealed with an epoxy resin excellent in mechanical strength.

Though irrelevant from the problem to be solved by this invention, Patent Publication 3 discloses that reflectance of light from a light-emitting element is increased by adding titanium oxide to the die-bonding member for fixing the light-emitting element.

Patent Publication 1: JP-A-2004-221308

Patent Publication 2: JP-A-2006-335857

Patent Publication 3: JP-A-2006-229249

However, according to experiment results of the inventors, it was impossible to achieve satisfactory effects for discoloration prevention and luminous intensity reduction prevention of the sealant material and the die-bonding member with the use of the silicone resins disclosed in Patent Publication 1 and Patent Publication 2 as the sealant material.

### SUMMARY OF THE INVENTION

This invention has been accomplished in view of the above-described conventional situation and has the aim of providing a light emission device wherein a sealant material and a die-bonding member are prevented from discoloration and luminous intensity reduction.

The inventors have found an unexpected fact that, when a light-emitting element wherein a sealant material and a die-bonding member are discolored is further driven after the discoloration, the discolored part is gradually faded to cause an increase in luminous intensity again. As a result of extensive research on the phenomenon, the inventors have assumed that the cause of discoloration is a decomposition product of the sealant material and that the reason for the color fading due to long-time emission is an oxidative decomposition of the causative substance for the discoloration due to the extended light irradiation. Also, the inventors have accomplished this invention based on the findings that the luminous intensity of light emission device is prevented from reduction by dispersing titanium oxide into the die-bonding member, thereby causing oxidative decomposition of causative substance of discoloration by a photo-oxidation catalyst function of the titanium oxide.

That is, the light emission device of this invention comprises a light-emitting element fixed on a substrate with a die-bonding member and a resin sealing member for sealing the light-emitting element with a transparent resin, wherein the die-bonding member is obtainable by dispersing titanium oxide into an alicyclic epoxy resin obtainable by curing an alicyclic epoxy compound with a curing agent.

In the light emission device of this invention, the alicyclic epoxy resin used as the die-bonding member and obtainable by curing the alicyclic epoxy compound with the curing agent is excellent in chemical resistance unlike a hydrogenated bisphenol A epoxy which is synthesized from bisphenol A and epichlorhydrin. Therefore, the alicyclic epoxy resin has a strong resistance against discoloration by light irradiation. Further, due to titanium oxide dispersed into the die-bonding member, holes having strong oxidative power are generated by the light irradiation in titanium oxide, and active oxygen species that are generated by oxidation of oxygen by the holes, such as superoxide anion and hydroxyl anion, eliminate discoloration-causing substance through oxidative decomposition. Accordingly, even when the die-bonding member is discolored, it is possible to decolor the discolored part. In view of the fact that the photo-oxidation reaction by titanium oxide requires existence of oxygen and water, it is considered that water absorbed by titanium oxide is involved as the water, and that oxygen dissolved in the sealant material migrates to titanium oxide by diffusion as the oxygen.

Therefore, in the light emission device of this invention, the causative substance of discoloration is readily subjected to oxidative decomposition, and light emission device maintains luminous intensity thereof due to the oxidative decomposition of causative substance of discoloration.

In the light emission device of this invention, examples of the alicyclic epoxy compound to be used for the die-bonding member include 3,4-epoxycyclohexylmethyl-3,4-epoxycyclohexylcarboxylate and the like. As the curing agent, an acid anhydride, amines, imidazole, polymercaptan, and the like may be used, among which the acid anhydride is preferred.

In the light emission apparatus of this invention, the resin sealing member may preferably be comprised of a silicone sealing part for sealing the light-emitting element with a silicone resin and an epoxy sealing part for further sealing the silicone sealing part with an epoxy resin. With such constitution, it is possible to minimize discoloration of the epoxy sealing part since the epoxy resin that can be discolored by light irradiation does not directly contact the light-emitting element.

Also, the silicone sealing part may preferably comprise polydimethylsiloxane. The methyl-based silicone resin is excellent in light resistance and heat resistance.

Further, the epoxy sealing part may preferably comprise an alicyclic epoxy resin. The alicyclic epoxy resin is excellent in chemical resistance and has strong resistance against discoloration by light irradiation.

In the light emission device of this invention, any of anatase titanium oxide, brookite titanium oxide, and rutile titanium oxide, may be used as the titanium oxide. Anatase titanium oxide enables rapid progress of photo-oxidation reaction since it has a higher activity as a photo-oxidation catalyst as compared to brookite titanium oxide and rutile titanium oxide, and particles of a fine particle diameter of brookite titanium oxide are easily available. With the use of rutile titanium oxide, luminous intensity is increased due to its high reflectance. It is preferable to adhere a metal that enhances activity of a photocatalyst, such as Pt, to titanium oxide.

### BRIEF DESCRIPTION OF THE DRAWINGS

FIG. 1 is a schematic sectional view showing a light emission device of Example 1.

FIG. 2 is a schematic sectional view showing a state in which a light-emitting element is mounted on a lead frame.

FIG. 3 is a schematic sectional view showing a state in which the light-emitting element mounted on the lead frame is sealed with a silicone resin.

FIG. 4 is a graph showing a relationship between an experiment time and relative luminous intensity in a durability experiment of light emission, devices of Example 1, Example 2, Experimental Example 1, and Experimental Example 2.

FIG. 5 is a graph showing a relationship between an experiment time and relative luminous intensity in a durability experiment of light emission devices of Comparative Example 1 and Comparative Example 3.

FIG. 6 is a graph showing a relationship between an experiment time and relative luminous intensity in a durability experiment of light emission device of Comparative Example 4.

### DESCRIPTION OF THE PREFERRED EMBODIMENTS

The light emission device of this invention is applied to LEDs such as of the top view type, side view type, shell type, and COB type irrespective of the shape thereof. The prominent effect is exhibited particularly in light-emitting elements emitting light of a short wavelength. More specific examples include a blue LED, an ultraviolet LED, a monochrome white LED or a white LED with fluorescent material using the ultraviolet LED, and the like. The light of short wavelength has a large energy to cause prominent discoloration of the sealant material and the die-bonding member. As the light-emitting element emitting light of short wavelength, a group III nitride-based compound semiconductor light-emitting element may preferably be used. As used herein, the group III nitride-based compound semiconductor is represented by a general formula of AlₓGa_{y}In_{1-X-Y}N (wherein 0<X<1, 0<Y<1, 0<X+Y<1); a part of the group III elements may be substituted by boron (B), thallium (Tl), or the like; and at least a part of nitride (N) may be substituted by phosphor (P), arsenic (As), antimony (Sb), bismuth (Bi), or the like.

The group III nitride-based compound semiconductor may contain an arbitrary dopant. As an n-type impurity, silicon Si), germanium, (Ge), serene (Se) tellurium (Te), carbon (C), and the like may be used. As a p-type impurity, magnesium (Mg), zinc (Zn), beryllium (Be), calcium (Ca), strontium (Sr), barium (Ba), and the like may be used. After doping with the p-type impurity, the group III nitride-based compound semiconductor may be exposed to heat by electron beam irradiation, plasma irradiation, or a furnace, and such heat exposure is not essential.

A group III nitride-based compound semiconductor layer may be formed by MOCVD (metalorganic chemical vapor deposition). It is unnecessary to form all of semiconductor layers forming the element by MOCVD, and it is possible to employ molecular beam epitaxy (MBE), halide vapor phase epitaxy (HVPE), sputtering, ion plating, and the like in combination.

As the structure of the light-emitting element, a homo-structure having an MIS junction, a PIN junction, or a pn junction, a hetero-structure, or a double hetero-structure may be used. For a light-emitting layer, a quantum well structure (single quantum well structure or multiple quantum well structure) may be used. Usable as the group III nitride-based compound semiconductor light-emitting element are those of a face-up type wherein a main light reception/emission direction (electrode surface) is a light axis direction of an optical device or a flip chip type wherein a main light receiving/emitting direction is a direction reverse to a light axis direction to use reflected light.

Though the alicyclic epoxy compound is used for the die-bonding member in this invention, a methyl-based silicone resin may be used for the die-bonding member in place of the alicyclic epoxy compound. The methyl-based silicone resin is a resin comprising polydimethylsiloxane as a main framework wherein 80% or more of functional groups bonding to silicon atoms is methyl groups. Specific examples thereof include organopolysiloxane for sealing light-emitting element as disclosed in Patent Publication 1 and Patent Publication 2. According to the experiment results of the inventors, remarkable prevention of discoloration of the die-bonding member is achieved by using the methyl-based silicone resin as a resin component of the die-bonding member. Since titanium oxide is dispersed into the die-bonding member, the discoloration-causing substance are decomposed and eliminated due to the above-described photo-oxidation effect of titanium oxide.

Therefore, the causative substance of discoloration is readily subjected to oxidative decomposition, and it is possible to maintain the luminous intensity of the light emission, device due to oxidative decomposition of causative substance of discoloration.

### EXAMPLES

Hereinafter, the constitution of this invention will be described in more details by using the following examples.

### Example 1

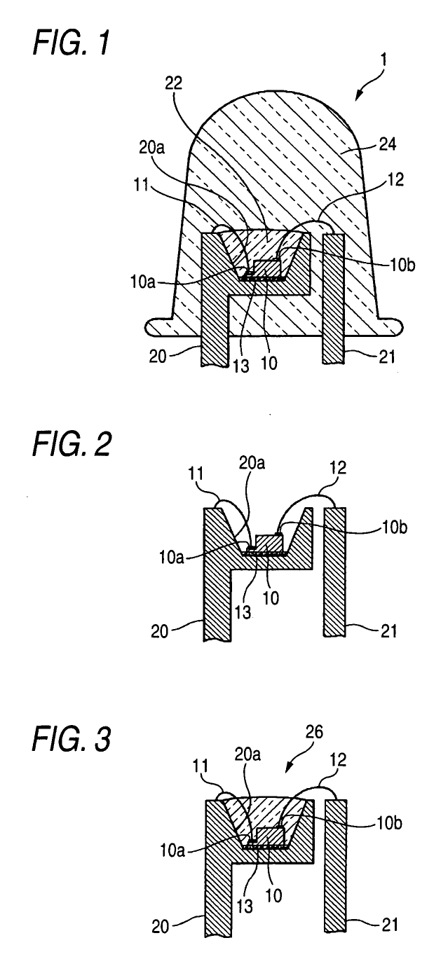

A light emission device of Example 1 is a shell type LED 1 as shown in FIG. 1, wherein a light emission element 10 is a light-emitting diode having a wavelength region of 457.5 to 460 nm and mounted by using a die-bonding member 13 made from an epoxy resin on a cup-like part 20a provided at the tip of a lead frame 20. The epoxy resin is obtained by heat curing an epoxy paste of the following composition.

| | |
|---|---|
| 3,4-epoxycyclohexylmethyl-3,4- | 40 parts by weight |
| epoxycyclohexylcarboxylate (ADC): | |
| Methyl-hexahydrophthalic acid anhydride: | 49 parts by weight |
| Rutile titanium oxide: | 1 part by weight |

An n-electrode 10a and a p-electrode 10b of the light-emitting element 10 are wire-bonded to the lead frames 20 and 21 with wires 11 and 12. The cup-like part 20a is filled with a silicone resin 22. The silicone resin 22 has the following composition.

### Dimethylsiloxane: 89.5 wt %

### Vinylsiloxane: 0.4 wt %

Si—H group-containing silicon compound: 1.0 wt %

An epoxy resin 24 further seals the silicone resin part 22 from above in the form of a shell. The epoxy resin 24 is obtained by heat curing an epoxy adhesive agent of the following composition. The silicone resin 22 is the silicone sealing part and the epoxy resin is the epoxy sealing part.

| | |
|---|---|
| 3,4-epoxycyclohexylmethyl-3,4- | 30 parts by weight |
| epoxycyclohexylcarboxylate (ADC): | |
| Bisphenol A: | 70 parts by weight |
| 4-methylcyclohexane-1,2-dicarboxylic acid | 100 parts by weight |
| anhydride: | |

The shell type LED 1 of Example 1 having the above-described constitution is produced as described below.

The lead frame 20 provided with the cup-like part 20a at the tip thereof and the lead frame 21 are used, and the light-emitting element 10 is fixed to the cup-like part 20a with the epoxy paste as shown in FIG. 2. As shown in FIG. 3, the silicone resin 22 is filled into the cup-like part 20a, followed by heat curing, thereby obtaining an LED main body 26. The epoxy resin 24 is formed into a shell from above the silicone resin 22 to obtain the light emission device 1 of Example 1 shown in FIG. 1.

In a light emission device of Example 2, a light-emitting element has a light emission wavelength of 450 to 452.5 nm. Since other parts are the same as those of the light emission device of Example 1, description thereof is omitted.

### Experimental Example 1

In a light emission device of Experimental Example 1, a die-bonding agent for mounting the light-emitting element has the following composition.

### Dimethylsiloxane: 90 wt %

Si—H group-containing silicon compound: 7 wt %
Si—CH═CH₂ group-containing silicon compound: 3 wt %
Rutile titanium oxide: 20 parts by weight when a total of the above 3 ingredients is 100 parts by weight.

Since other parts of Experimental Example 1 are the same as those of the light emission device of Example 1, description thereof is omitted.

### Experimental Example 2

In a light emission device of Experimental Example 2, the die-bonding agent same as that of Experimental Example 1 was used. Since other parts of Experimental Example 2 are the same as those of the light emission device of Example 2, description thereof is omitted.

### Comparative Example 1

In a light emission device of Comparative Example 1, titanium oxide is not added to the die-bonding agent for mounting the light-emitting element.

Since other parts of Comparative Example 1 are the same as those of the light emission device of Example 1, description thereof is omitted.

### Comparative Example 2

In a light emission device of Comparative Example 2, titanium oxide was not added to the die-bonding agent for mounting the light-emitting element. Since other parts of Comparative Example 1 are the same as those of the light emission device of Experimental Example 1, description thereof is omitted.

### Comparative Example 3

In a light emission device of Comparative Example 3, titanium oxide was not added to the die-bonding agent for mounting the light-emitting element, and a die-bonding agent having the following composition was used. Since other parts of Comparative Example 3 are the same as those of the light emission device of Example 1, description thereof is omitted.

| | |
|---|---|
| 3,4-epoxycyclohexylmethyl-3,4- | 54 parts by weight |
| epoxycyclohexylcarboxylate (ADC): | |
| Bisphenol A: | 46 parts by weight |
| Methyl-hexahydrophthalic acid anhydride | 100 parts by weight |
| (MHHPA): | |

### Comparative Example 4

In Comparative Example 4, a die bonding agent obtained by adding 1 part by weight of rutile titanium oxide to 100 parts by weight of the die-bonding agent of Comparative Example 3 was used. Since other conditions are the same as those of Comparative Example 3, description thereof is omitted.

### <Durability Experiment>

### (Durability Experiment 1>

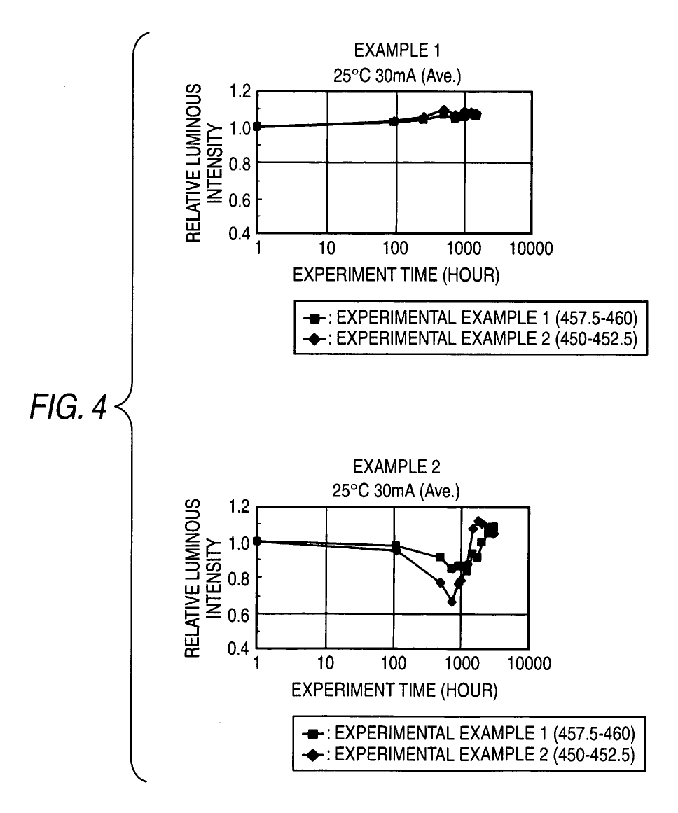

A long time durability experiment (25° C., 30 mA) was conducted on the light emission devices of Example 1, Example 2, Experimental Example 1, and Experimental Example 2 to examine changes in light intensity. As a result, a reduction in luminous intensity was hardly or never observed in the light emission devices of Examples 1 and 2 and Experimental Examples 1 and 2 until 100 hours as shown in FIG. 4. As a result of continuing the long time durability experiment, relative luminous intensity of Example 1 was gradually reduced after 100 hours until 1,000 hours to reach 0.80 at the lowest (0.62 in Example 2), and the relative luminous intensity recovered after reaching to the lowest relative luminous intensity. It is considered that such phenomenon occurred since discoloration-causing substance that was generated by light irradiation was decomposed and decolored by the titanium oxide catalyst by the further light irradiation. The relative luminous intensity scarcely changed in Experimental Examples 1 and 2 after 1,000 hours have passed.

### (Durability Experiment 2)

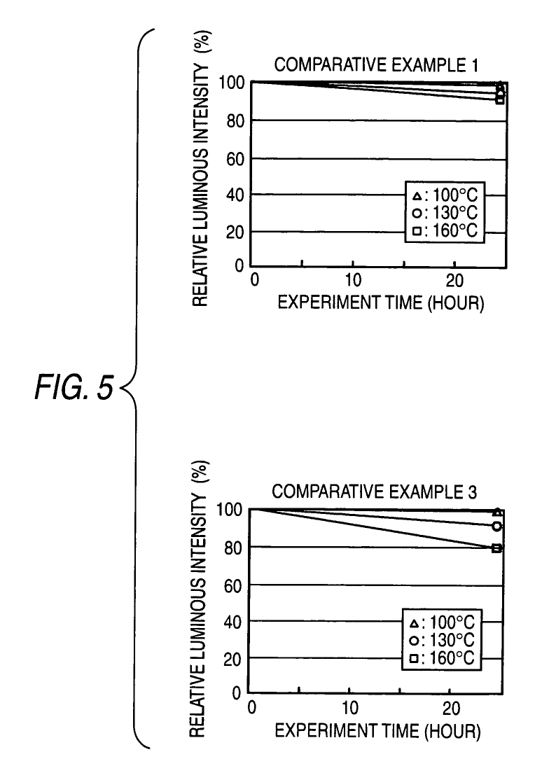

A long time durability experiment was conducted on the light emission devices of Comparative Example 1 and Comparative Example 3 to examine changes in light intensity. As a result, Comparative Example 3 using the die-bonding agent containing bisphenol A showed a large degree of discoloration as compared to Comparative Example 1 using the alicyclic epoxy resin as the binder component and not containing bisphenol A as shown in FIG. 5.

### (Durability Experiment 3)

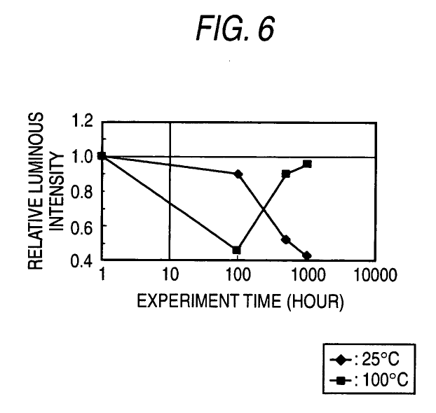

Long time durability experiments at 25° C. and 30 mA and 100° C. and 30 mA were conducted on the light emission device of Comparative Example 4 to examine a change in light intensity. As a result, luminous intensity decreased along with the light emission time as shown in FIG. 6, and relative luminous intensity at 1,000 under the condition of 25° C. was largely decreased to 0.43. Further, luminous intensity under the condition of 100° C. was largely reduced to 0.46 by a short light emission time of 100 hours. In case of continuing the long time light emission, contrary to the above result, the luminous intensity was increased. It is considered that the increase in luminous intensity occurred since discoloration-causing substance that was generated by light irradiation was decomposed and decolored by the titanium oxide catalyst by the further light irradiation.

This invention is not at all limited to the above-described examples. Various modifications that are achieved by those skilled in the art without deviating from the scope of claims are encompassed by this invention.

What is claimed is:

1. A light emission device, comprising:
a light-emitting element fixed on a substrate with a die-bonding member; and
a resin sealing member for sealing the light-emitting element with a transparent resin;
wherein the die-bonding member is obtainable by dispersing titanium oxide into an alicyclic epoxy resin obtainable by curing an alicyclic epoxy compound with a curing agent.

2. The light emission device according to claim 1, wherein the resin sealing member comprises a silicone sealing part for sealing the light-emitting element with a silicone resin and an epoxy sealing part for further sealing the silicone sealing part with an epoxy resin.

3. The light emission device according to claim 1, wherein the silicone sealing part comprises a methyl-based silicone resin.

4. The light emission device according to claim 2, wherein the epoxy sealing part comprises an alicyclic epoxy resin.

5. The light emission device according to claim 1, wherein the titanium oxide is anatase titanium oxide.
